(19) United States
(12) Patent Application Publication
(10) Pub. No.: US 2024/0353752 A1
(43) Pub. Date: Oct. 24, 2024

(54) ORGANOTIN CLUSTER PHOTORESISTS AND STABILIZATION METHODS

(71) Applicant: Feng Lu, Irvine, CA (US)

(72) Inventor: Feng Lu, Irvine, CA (US)

(21) Appl. No.: 18/634,068

(22) Filed: Apr. 12, 2024

Related U.S. Application Data
(60) Provisional application No. 63/460,743, filed on Apr. 20, 2023.

(51) Int. Cl. G03F 7/004; C07F 7/22

(52) U.S. Cl. CPC G03F 7/0044; C07F 7/2224; C07F 7/2296

(57) ABSTRACT

The present disclosure is related to organotin cluster photoresists and stabilization methods, particularly for extreme ultraviolet radiation (EUV) photolithography. The organotin cluster photoresists comprise one or more represented by chemical formulas [RR¹Sn]₃E₃, and [RSn]₄E₆. The stabilization methods include the application of organic molecules as additives to stabilize organotin cluster photoresists.

### CROSS REFERENCE TO RELATED APPLICATIONS

This application claims priority to U.S. provisional patent application No. 63/460,743, filed on Apr. 20, 2023 to Lu, entitled “Organotin cluster photoresists and stabilization methods”, of which is entirely incorporated herein by reference.

### FIELD OF INVENTION

The present invention relates to organotin cluster photoresists and stabilization methods, particularly for extreme ultraviolet radiation (EUV) photolithography.

### BACKGROUND

With the development of the semiconductor industry, nanoscale patterns have been in pursuit of higher devices density, higher performance, and lower costs. Reducing semiconductor feature size has become a grand challenge. Photolithography has been applied for creating microelectronic patterns over decades. Extreme ultraviolet (EUV) lithography is under development for mass production of smaller semiconductor devices feature size and increasement of devise density on a semiconductor wafer. EUV lithography is a pattern-forming technology using wavelength of 13.5 nm as an exposure light source to manufacture high-performance integrated circuits containing high-density structures patterned with nanometer scale. The application of EUV lithography can make extremely fine pattern with smaller width as equal to or less than 7 nm. Therefore, EUV lithography becomes one significant tool and technology for manufacturing next generation semiconductor devices.

In order to improve EUV lithography for smaller level, wafer exposure throughput can be improved through increased exposure power or increased photoresist sensitivity. Photoresists are radiation sensitive materials upon irradiation with relevant chemical transformation occurs in the exposed region, which would result in different properties between the exposed and unexposed regions. The properties of EUV photoresist, such as resolution, sensitivity, line edge roughness (LER), line width roughness (LWR), etch resistance and ability to form thinner layer are important in photolithography.

Organometallic compounds have high ultraviolet light adsorption because metals have high adsorption capacity of ultraviolet radiation with various carbon-metal (C-M) bond dissociation energy (BDE), and then can be used as photoresists and/or precursors for photolithography at smaller level (e.g., <7 nm), which is of great interests for radiation lithography. Among those promising advanced materials, particularly organometallic tin compounds can provide photoresist patterning with significant advantages, such as improved resolution, sensitivity, etch resistance, and lower line width/edge roughness without pattern collapse because of strong EUV radiation adsorption of tin, which have been demonstrated.

Organotin clusters have been demonstrated as EUV photoresists, which provide promising approach for the development of further smaller features such as <7 nm. However, the poor storage stability, poor solubility, and short shelf time with aggregation or precipitation formation during storage have become severe issues for distribution and application in photolithography patterning.

Organic molecules containing various functional groups, such as —OH, —SH, —COOH, —NH₂, or phosphine, can be used as additives to stabilize organotin compounds, clusters, or nanoparticles photoresist with improved stability and/or solubility. The organic additives comprise organic thiol, organic alcohol, organic amine, organic amide, organic carboxylic acid, organic phosphine, organic phosphine oxide, or organic phosphonic acid, which can be adsorbed, grafted, immobilized, anchored, or coordinated on organotin photoresists, and then avoid potential aggregation, precipitation, or age. For example, after exposure, the exposed portion of organic additive-stabilized organotin photoresists convert to polynuclear oxo-hydroxide network or metal oxides with poor solubility in solvents. While the unexposed portion of organotin photoresist can be removed by the developers.

### SUMMARY

In a first aspect, the present invention pertains to organotin cluster photoresists and stabilization methods, particularly for extreme ultraviolet (EUV) photolithography patterning. The present invention pertains to organic molecules stabilizing organotin cluster photoresists for photolithography patterning. The present invention is to provide improved photosensitivity, stability, solubility, uniformity, and shelf life of organic molecules-stabilized organotin cluster photoresists for substrate surface coating without aggregation or precipitation generation.

In another aspect, the invention pertains to radiation sensitive organotin cluster compounds as photoresists or precursors represented by chemical formulas [RR¹Sn]₃E₃, [RSn]₄E₆ as below:

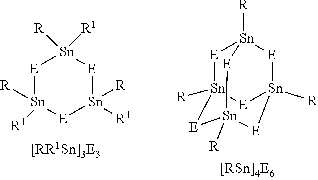

wherein R is a substituted or unsubstituted cycloalkenyl group with 3 to 20 carbon atoms; R¹ is a substituted or unsubstituted alkyl, alkenyl, alkynyl, cycloalkyl, or cycloalkenyl group with 1 to 20 carbon atoms, or a substituted or unsubstituted aryl group with 6-20 carbon atoms; E=O, S, Se, or Te.

In a further aspect, the invention pertains to stabilization methods for organotin cluster photoresists, which may overcome the disadvantages like poor stability and solubility and short shelf time from non-stabilized conventional organotin cluster photoresists. The stabilization methods comprise the application of organic molecules to stabilize the as-formed organotin clusters, and to prevent from aggregation occurred or precipitate formation. The aggregation and precipitation can lead to scums or defects on the surface of substrates during photolithography patterning. The organic molecules contain various functional groups, such as —SH, —OH, —NH₂, —COOH, —CONH₂, including but not limited to, organic thiol, organic alcohol, organic amine, organic amide, organic carboxylic acid, organic phosphine, phosphine oxide, or phosphonic acid.

In other aspects, the present invention is to provide preparation and purification methodology of organotin cluster photoresist with high purity for photolithography (e.g., EUV, <7 nm). The present invention is further to provide an alternative organotin cluster photoresist with higher resolution, sensitivity, and lower line width roughness without pattern collapse during microelectronic patterning.

The organic molecules-stabilized organotin cluster photoresist can dissolve in appropriate organic solvents to form uniformed solution composition for deposition on the surface of substrate for photolithography patterning.

In an addition aspect, the invention pertains to methods for organotin cluster photoresists deposition on a surface of semiconductor substrate by wet deposition like spin-on coating, spray coating, dip coating, vapor deposition, knife edge coating, or dry deposition like chemical vapor deposition, physical vapor deposition, atomic layer deposition, or other approaches.

In a further aspect, the invention pertains to radiation sensitive organometallic tin compounds as precursors represented by FIGS. 1-27 for preparation of organotin cluster compounds as photoresists, including but not limited to, alkyl-, alkenyl-, alkynyl-, cycloalkyl-, cycloalkenyl-containing organometallic tin compounds. The hydrolysable organometallic tin precursors for generation of organotin cluster compounds, include, but not limited to, oxide hydroxide (stannonic acid), anhydride, hydroxide, alkoxides, amides, distannoxane (oxo), oxides, esters, or halides.

In some embodiments, cycloalkenyl group comprises a substituted and unsubstituted C4 to C8 cyclic aliphatic unsaturated organic groups including at least one double bond as below.

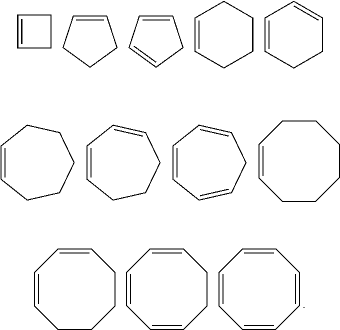

In some embodiments, cycloalkenyl comprises cyclopentadienyl (C₅H₅, or Cp), or substituted cyclopentadienyl C₅H₄R′, C₅H₃R′₂, C₅H₂R′₃, C₅HR′₄, or C₅R'₅ group with hapticity of η¹, η², η³, η⁴, or η⁵ of isomers; wherein R′ is H, a substituted or unsubstituted alkyl, alkenyl, alkynyl, or cycloalkyl group with 1 to 20 carbon atoms, or a substituted or unsubstituted aryl group with 6-20 carbon atoms, or other functional groups such as amino, cyano, ether, ester, halide, nitro, silyl, thiol, or carbonyl group.

The invention relates to radiation sensitive organotin cluster photoresists, which can be efficiently patterned after exposure to ultraviolet light, extreme ultraviolet light, electron beam radiation, X-ray radiation, or other likes, to form high resolution patterns with low line width roughness, high resolution, low dose, and large contrast, such as for <7 nm.

### BRIEF DESCRIPTION OF THE DRAWINGS

FIGS. 1-27 represent the chemical formulas of organometallic tin precursors for preparation of organotin cluster compounds as photoresists, wherein R is a substituted or unsubstituted cycloalkenyl group with 3 to 20 carbon atoms, R¹, R², R³ are independently H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or other functional groups such as amino, cyano, ether, ester, halide, nitro, silyl, thiol, or carbonyl group; X=F, Cl, Br, or I; E=O, S, Se, or Te.

FIG. 28 illustrates a flowchart of organometallic tin photoresist radiation photolithography patterning processing on the surface of semiconductor substrate surface.

### DETAILED DESCRIPTION

The present invention pertains to organotin cluster photoresists and stabilization methods. The present invention is to provide the stabilization methods of organotin cluster photoresists, particularly, suitable for EUV lithography (e.g. <7 nm). The present invention is further to provide organic molecules-stabilized organotin cluster photoresists with higher resolution, sensitivity, solubility, stability, shelf life, and lower line width roughness without pattern collapse during microelectronic patterning. The photosensitivity, thermostability, and uniformity of organotin cluster photoresists determine the high resolution and efficiency for photolithography patterning.

As described herein, the singular forms “a”, “an”, “one”, and “the” are intended to include the plural forms as well, unless clearly indicated otherwise. Further, the expression “one of,” “at least one of,” “any”, and “selected from,” when preceding a list of elements, modify the entire list of elements and do not modify the individual elements of the list.

As described herein, the terms “includes”, “including”, “comprise”, or “comprising”, when used in this specification, specify the presence of the stated features, steps, operations, elements, components, but do not preclude the presence or addition of one or more other features, steps, operations, elements, components, and/or group thereof.

As described herein, the term “and/or” includes any and all combinations of one or more of the associated listed items. Further, the use of “may” when describing embodiments of the present disclosure refers to “one or more embodiments of the present disclosure”.

As described herein, the terms “use,” “using,” and “used” may be considered synonymous with the terms “utilize,” “utilized”, “applied”, respectively. In addition, the terms “about,” “only,” and similar terms are used as terms of approximation and not as terms of degree, and are intended to account for the inherent deviation in measured or calculated values that would be recognized by those of ordinary skill in the art.

The terms “alkyl, alkenyl, or alkynyl” refers to hydrocarbon of 1 to 20 carbon atoms. The terms “cycloalkyl, or cycloalkenyl” refers to cyclic hydrocarbon of 3 to 20 carbon atoms. The term “aryl” refers to unsubstituted or substituted aromatic group with 6-20 carbon atoms. The term “alkylene” refers to a saturated divalent hydrocarbons by removal of two hydrogen atoms from a saturated hydrocarbons of 1 to 20 carbon atoms, e.g., methylene (—CH₂—), ethylene (—CH₂CH₂—), propylene (—CH₂CH₂CH₂—), or the like.

The term “amine” refers to primary (—NH₂), secondary (—NHR), tertiary (—NR₂) amine group. The term “cyclic amine” refers to [R′—NH—R″], wherein [R′—R″] is cyclic substituted and unsubstituted C3 to C8 organic groups, including, but not limited to:

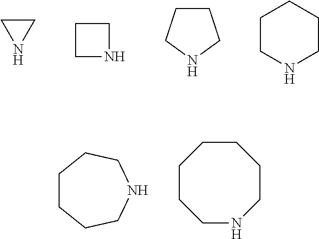

The term “ether” refers to the R′—O—R″ group. The term “cyclic ether” refers to the [R′—O—R″], wherein [R′—R″] is cyclic substituted and unsubstituted C3 to C8 organic groups, including, but not limited to:

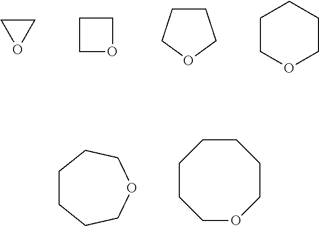

The term “ester” refers to the R′—(C═O)—O—R″ group. The term “cyclic ester” refers to the [R—(C═O)—O—R′], wherein [R′—R″] is cyclic substituted and unsubstituted C4 to C8 organic groups, including, but not limited to:

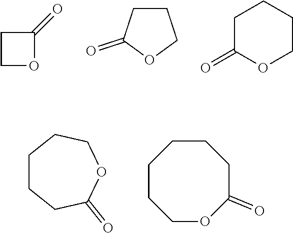

The term “halide” refers to the F, Cl, Br, or I. The term “nitro” refers to the —NO₂. The term “silyl” refers to the —SiR′—, —SiR′₂—, or —SiR′₃ group. The term “thiol” refers to —SH group. The term “carbonyl” refers to the —C═O group. The term “oxo” refers to —O—, or ═O.

In the above described, R′, R″ are independently a substituted or unsubstituted alkyl, alkenyl, alkynyl, cycloalkyl, or cycloalkenyl group with 1 to 20 carbon atoms, or a substituted or unsubstituted aryl group with 6-20 carbon atoms.

In the present disclosure, the term “substituted” refers to replacement of a hydrogen atom with a C1 to C20 alkyl group, a C2 to C20 alkene group, a C2 to C20 alkyne group, a C3 to C20 cycloalkyl group, a C6 to C20 aryl group, or other relevant groups, such as amide, amine, cyclic amine, cyano, ether, cyclic ether, ester, cyclic ester, halide, imine, nitro, silyl, thiol, or carbonyl group.

The term “η¹” refers to one carbon atom bonded to one metal atom. The term “η²” refers to two carbon atoms bonded to one metal atom. The term “η³” refers to three carbon atoms bonded to one metal atom. The term “η⁴” refers to four carbon atoms bonded to one metal atom. The term “η⁵” refers to five carbon atoms bonded to one metal atom. For example, η¹, η⁵ are correspondingly depicted as following (M=metal):

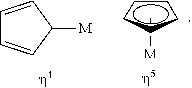

In some embodiments, η⁵-organometallic compounds comprise half-sandwich or sandwich-type compounds bearing η⁵-C₅—Sn π bond.

EUV lithography is under the development for the mass production of next generation <7 nm node. EUV photoresists are required to achieve higher performance, higher sensitivity and resolution, and cost reduction.

EUV light has been applied for photolithography at about 13.5 nm. The EUV light can be generated from Sn plasma or Xe plasma source excited using high energy lasers or discharge pulses.

For conventional organic polymer photoresists, if the aspect ratio, which is the height divided by width, is too large that would lead to pattern structures susceptible to collapse, and also associated with surface tension, which would limit the application for smaller features like <7 nm.

For small feature sizes like <7 nm, such as 1-3 nm, the conventional chemically amplified (CA) organic polymer photoresists suffer from critical issues, such as poor EUV light adsorption, low resolution, high line edge roughness (LER), increased pattern collapses and defects. In order to overcome the disadvantages or drawbacks from conventional organic polymer photoresists or inorganic photoresists, novel organometallic photoresists, or organometallic photosensitive compositions, particularly for EUV, have been called for.

Organometallic photoresists are used in EUV lithography because metals have high adsorption capacity of EUV radiation. Radiation sensitivity and thermal-, oxygen- and moisture-stability are important for organometallic photoresists. In some embodiments, organometallic photoresists may adsorb moisture and oxygen, which may result in decreasing stability, as well decreasing solubility in developer solutions. In addition, in some embodiments, photoresist layer may outgas volatile components prior to the radiation exposure and development operations, which may negatively affect the photolithography performance, lead to pattern collapse, and increase defects.

In general, metal central plays the key role in determining the absorption of photo radiation of organometallic photoresists. The physical and chemical properties of organometallic compounds which are suitable for photoresists determine the relevant properties for photolithography, particularly for EUV and DUV, wherein bond dissociated energy (BDE) of M-C (metal-carbon bond) plays the key role. M is metal, including but not limited to, tin (Sn), indium (In), antimony (Sb), bismuth (Bi), manganese (Mn), vanadium (V), titanium (Ti), chromium (Cr), selenium (Se), tellurium (Te), zirconium (Zr), hafnium (Hf), gallium (Ga), or germanium (Ge). Particularly, organotin photoresists are suitable for EUV or DUV photolithography patterning.

Meanwhile for organometallic compounds, the metal-bonded organic ligands (M-R, M=metal, R=cleavable/hydrolysable organic ligands) may also influence the relevant absorption through M-C bonding.

Tin atom provides strong absorption of extreme ultraviolet (EUV) light at 13.5 nm, therein tin cations can be selected based on the desired radiation and absorption cross section. Meanwhile the organic ligand bonded to tin also has absorption of EUV light. Therefore, the tuning and modification of organic ligands can change sensitivity, radiation absorption, or desired control of material properties.

The bond dissociation energy (BDE) of Sn—C bond determines the light adsorption wavelength, corresponding smaller features, and patterned structures.

Organotin photoresists have excellent (e.g., suitable) sensitivity to high energy light (e.g., EUV, DUV, X-ray, or laser) due to tin strong absorption of extreme ultraviolet (EUV) at about 13.5 nm. Accordingly, organotin photoresists have improved sensitivity, resolution, stability, compared with conventional organic polymer or inorganic photoresists.

In some embodiments, organotin photoresist comprises small organometallic tin compound, organotin cluster, or organotin polymer with large molecular weight.

The organotin cluster photoresists comprise organic ligand, Sn—C bond, or Sn—O bond, or Sn—O—Sn bond, or Sn—S bond, or Sn—Se bond, or Sn—Te bond, providing desirable radiation sensitive and stabilization for photolithography patterning. The organotin cluster photoresists possess excellent properties for the application of photolithographic patterning.

Organotin photoresist composition according to embodiments of the present disclosure may have improved etch resistance, sensitivity and resolution, compared with relevant conventional organic polymer or inorganic resists, wherein oxygen, nitrogen, or various groups are bonded to tin metal as described above.

Organotin photoresist layer is patterned by exposure to actinic radiation. Typically, the chemical properties of the photoresist regions struck by incident radiation change in a manner that depends on the type of photoresist used. Photoresist can be positive resist or negative resist. In some embodiments, positive resist refer to a photoresist material that when exposed to radiation (e.g., EUV) becomes soluble in a developer, while the region of the photoresist that is non-exposed (or exposed less) is insoluble in the developer. In some embodiments, on the contrary, negative resist refers to a photoresist material that when exposed to radiation becomes insoluble in the developer, while the region of the photoresist that is non-exposed (or exposed less) is soluble in the developer.

Examples of organotin cluster photoresists that may be used in implementations of the invention, are represented by [RR¹Sn]₃E₃, or [RSn]₄E₆ depicted as following:

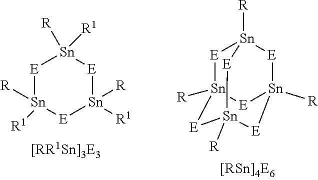

wherein R is a substituted or unsubstituted cycloalkenyl group with 3 to 20 carbon atoms; R¹ is a substituted or unsubstituted alkyl, alkenyl, alkynyl, cycloalkyl, or cycloalkenyl group with 1 to 20 carbon atoms, or a substituted or unsubstituted aryl group with 6-20 carbon atoms; E=O, S, Se, or Te. In some embodiments, cycloalkenyl group comprises a substituted and unsubstituted C4 to C8 cyclic aliphatic unsaturated organic groups including at least one double bond. In some embodiments, cycloalkenyl is one or more selected from the following:

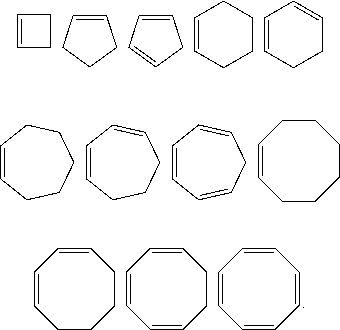

In some embodiments, cycloalkenyl is cyclopentadienyl C₅H₅, or substituted cyclopentadienyl C₅H₄R′, C₅H₃R′₂, C₅H₂R′₃, C₅HR′₄, or C₅R'₅ with hapticity of η¹, η², η³, η⁴ or η⁵ of isomers, wherein R′ is H, a substituted or unsubstituted alkyl, alkenyl, or alkynyl group with 1 to 20 carbon atoms, cycloalkyl group with 3 to 20 carbon atoms, or a substituted or unsubstituted aryl group with 6-20 carbon atoms, or an amino, cyano, ether, ester, halide, nitro, silyl, thiol, or carbonyl group. In some embodiments, organotin clusters [RR¹Sn]₃E₃, or [RSn]₄E₆ also may be used as precursors for the formation of patterning film.

As one of ordinary skill in the art will recognize, the chemical compounds listed here are merely intended as illustrated examples of the organotin clusters, and are not intended to limit the embodiments to only those organotin clusters specifically described. Rather, any suitable organotin clusters may be used, and all such organotin clusters are fully intended to be included within the scope of the present embodiments.

The radiation sensitive organotin cluster photoresists comprise polynuclear oxo or oxo-hydroxide networks, and organic ligands. However, the poor stability of conventional organotin cluster photoresists in solution after aged may lead to aggregation or precipitation with short shelf life for photolithography, which then may result in scums or defects during photolithography patterning.

The invention pertains to methods for preparation and purification of organotin precursors, organotin cluster compounds. All chemical manipulations, including preparation and purification, are performed under an inert atmosphere of purified nitrogen or argon in dry and degassed solvents by employing standard Schlenk techniques. In the present disclosure, the purification methods include, but not limited to, distillation, extraction, filtration, recrystallization, column chromatography, coordination, sublimation, or combinations thereof. For example, recrystallization can be carried out by slowly cooling down the hot solution to ambient temperature. In some embodiments, recrystallization may result in single crystals, which are suitable for X-ray diffraction analysis to determine molecular structures.

In one example embodiment, the reactions of RR¹SnX₂ (X=F, Cl, Br, or I) with MEH (M=Li, Na, or K, E=O, S, Se, or Te) afford [RR¹Sn]₃E₃ depicted as below:

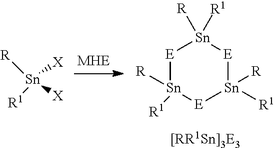

wherein R is a substituted or unsubstituted cycloalkenyl group with 3 to 20 carbon atoms; R¹ is a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, E is O, S, Se, or Te. For example, R, R¹ are cyclopentadienyl C₅H₅ group, or substituted cyclopentadienyl C₅H₄R′, C₅H₃R′₂, C₅H₂R′₃, C₅HR′₄, or C₅R'₅ group with hapticity of η¹, η², η³, η⁴, or η⁵ of isomers, wherein R′ is H, a substituted or unsubstituted alkyl, alkenyl, alkynyl, or cycloalkyl group with 1 to 20 carbon atoms, or a substituted or unsubstituted aryl group with 6-20 carbon atoms, or an amino, cyano, ether, ester, halide, nitro, silyl, thiol, or carbonyl group. For example, the reaction of Cp₂SnCl₂ (Cp=cyclopentadienyl) with NaOH in refluxing toluene resulted in [Cp₂Sn]₃O₃ under ambient conditions depicted as below:

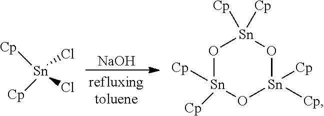

which is according to the reference, H. Puff, W. Schuh, R. Sievers, W. Wald, R. Zimmer, “Niedermolekular diorganozinn-sauerstoff-verbindungen: Di-t-butyl und di-tpamylzinnoxid”, Journal of Organometallic Chemistry, 260 (1984) 272-280, which is incorporated herein by reference.

In further one example embodiment, the reactions of RSnX₃ (X=F, Cl, Br, or I) with M₂E (M=Li, Na, or K; E=O, S, Se, or Te, e.g., Na₂O, Na₂S) in liquid ammonia at low temperature (e.g., −78° C.) result in organotin cluster [RSn]₄E₆ under ambient conditions depicted as below:

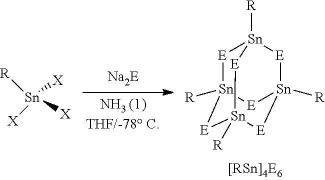

wherein R is a substituted or unsubstituted cycloalkenyl group with 3 to 20 carbon atoms. For example, R is cyclopentadienyl C₅H₅ group, or substituted cyclopentadienyl C₅H₄R′, C₅H₃R′₂, C₅H₂R′₃, C₅HR′₄, or C₅R'₅ group with hapticity of η¹, η², η³, η⁴, or η⁵ of isomers, wherein R′ is H, a substituted or unsubstituted alkyl, alkenyl, alkynyl, or cycloalkyl group with 1 to 20 carbon atoms, or a substituted or unsubstituted aryl group with 6-20 carbon atoms, or an amino, cyano, ether, ester, halide, nitro, silyl, thiol, or carbonyl group. In some embodiments, E is O depicted as below:

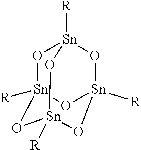

For example, the reaction of CpSnCR₃ with Na₂O afforded organotin cluster [Cp₃Sn]₄O₆ in in liquid ammonia at −78° C.

In some embodiments, the radiation sensitive organotin cluster photoresists contain polynuclear oxo, oxo-hydroxide networks, cleavable or hydrolysable organic ligands. However, the poor stability of organotin cluster photoresist composition after aged may lead to aggregation, coagulation, or precipitation with short shelf life, which may result in scums or defects during photolithography patterning, and limit the real application in patterning.

In some embodiments, the hydrolysable ligands of organotin photoresist precursors carry out hydrolysis with water or moisture from promoting agent to form free hydroxyl (—OH) groups, and then condensation to form organotin clusters. In some embodiments, in situ hydrolysis of organometallic precursors form organometallic dimer represented by (RₙM)₂(OH)₂L₄₋ₙ(H₂O)₂ (M=metal, R=organic ligand). The aggregation of organotin clusters in the presence of organometallic dimer bearing free —OH groups is prevented due to the complete hydrolysis of organometallic dimer. The aggregation of organotin clusters would bridge over proximate resist patterns and then lead to scum.

In some embodiments, an organotin photoresist precursor solution deposits over the surface of substrate or layer to form photoresist layer through in situ hydrolysis with water, or alternative bases like tetramethyl ammonium hydroxide. The baking of the formed photoresist layer at an elevated temperature result in hydrolysis of organometallic compound and subsequent condensation to form organometallic tin oxide hydroxide clusters. After exposure to EUV lithography or e-beam lithography, patterning radiation causes Sn—C bond cleavage and crosslinking of the organometallic tin oxide hydroxide clusters in the exposed portions of photoresists, and then resulted in a stable metal oxide (MOₓ).

In some embodiments, the stability of organotin photoresist in solution can be improved by adding organic molecule as stabilizing additive. The organic additive-stabilized organotin photoresist composition possess improved stability, solubility, uniformity, or shelf life for photolithography patterning.

In some embodiments, organic molecule as stabilizing additive includes, but not limited to, organic thiol, organic alcohol, organic amine, organic amide, organic carboxylic acid, organic phosphine, phosphine oxide, or organic phosphonic acid.

In some embodiments, organic thiol includes, but not limited to, 1-dodecanethiol, 2-dodecanethiol, 1,12-dodecanedithiol, 1-docosanethiol, 1-decanethiol, 1-heptanethiol, 2-heptanethiol, 1-heptadecanethiol, 1-hexanethiol, 1-hexadecanethiol, 1-nonanethiol, 1-octadecanethiol, 1-octanethiol, 1-pentadecanethiol, 1-tetradecaenthiol, 1-tridecanethiol, 1-undecanethiol, 1,8-octanedithiol, 1,2-ethanedithiol, or a combination thereof.

In some embodiments, organic alcohol includes, but not limited to, 1-dodecanol, 1-octanol, 1-hexadecanol, 1-heptanol, 1-heptadecanol, 1-decanol, 1-undecanol, 1-dodecanol, 1-tridecanol, 1-tetradecaonl, 1-nonaol, 1,10-decanediol, 1,2-hexadecanediol, 1,12-dodecanediol, 1,8-octanediol, 1,11-undecanediol, 2-mercaptoethanol, or a combination thereof.

In some embodiments, organic amine includes, but not limited to, 1-heptadecyloctadecylamine, decylamine, dodecylamine, heptylamine, heptadecylamine, hexadecylamine, isotridecanamine, nonylamine, octadecylamine, octanamine, octylamine, pentadecylamine, tetradecylamine, tridecylamine, triethylamine, undecylamine, undecanamine, 1,8-diaminooctane, 1,9-diaminononane, 1,12-dodecanediamine, 1,11-undecanediamine, or a combination thereof.

In some embodiments, organic amide includes, but not limited to, decanamide, docosanamide, dodecanamide, heanoamide, heptanamide, heptadecanamide, hexadecanamide, icosanamide, nonanamide, nonadecanamide, nonaediamide, octanamide, oleamide, octadecanamide, octanediamide, pentadecanamide, tetradecanamide, tridecanamide, undecanamide, or a combination thereof.

In some embodiments, organic carboxylic acid includes, but not limited to, oleic acid, citric acid, decanoic acid, hexadecanedioic acid, lauric acid, nonanoic acid, octanoic acid, palmitic acid, suberic acid, undecanoic acid, 1,11-undecanedicarboxylic acid, thiolglycolic acid, mercaptoacetic acid, mercaptopropionic acid, or a combination thereof.

In some embodiments, organic phosphine, phosphine oxide, or phosphonic acid, include, but not limited to, trioctylphosphine, tributylphosphine, tris(dimethylamino)phosphine, tris(diethylamino)phosphine, trioctylphospine oxide, hexylphosphonic acid, octadecylphosphonic acid, 11-undecenyl phosphonic acid, or a combinations thereof.

In some embodiments, organic molecules-stabilized organotin cluster photoresists comprise functional groups, including but not limited to, ether, thiol, silyl, keto, cyano, carbonyl, or halogenated groups, or a combination thereof.

In some embodiments, organic molecules-stabilized organotin clusters comprise Sn—O, Sn—S, Sn—Se, Sn—Te, Sn—N, Sn—P bond, or Sn—O—Sn network. In some embodiments, organic molecules stabilizers may be adsorbed, grafted, immobilized, anchored, or coordinated on organotin clusters as supports. For example, organic thiolate may coordinate with tin of organotin clusters to form Sn—S bond, or support on the surface of organotin clusters.

The organic molecules-stabilized organotin cluster photoresists according to an embodiment can be prepared by addition of organic molecule stabilizer to the solution of organotin clusters under ambient condition, which were freshly prepared from organometallic tin compound precursors with appropriate agents such as active hydrogen/hydroxyl-containing (e.g., water, LiAlH₄, NaBH₄, NaOH, NH₄OH). The ambient condition includes temperature range from −196 to 300° C., inert N₂ or Ar atmosphere, or air atmosphere, in organic solvent or water. The addition of organic molecules stabilizers can be carried out during 0-24 hours after the generation of organotin clusters with or without isolation or purification, for example, after one hour. The active hydrogen/hydroxyl-containing agents include but not limited to water, LiAlH₄, LiBEt₃H, NaBH₄, NaH, CaH₂, bases (e.g., NaOH, KOH, NH₄OH), acids (e.g., HCl, acetic acid), or alcohols (e.g., methanol, ethanol). A person of ordinary skills in the art will recognize that the choice of organic molecules, concentrations, solution composition components, addition manner, or preparation strategy within the explicit ranges of above are contemplated and are within the present disclosure.

In some embodiments, organic molecules-stabilized organotin cluster photoresists are soluble in appropriate organic solvents with improved uniformity for photolithography pattern processing. The solution compositions can be formed by dissolving organic molecules-stabilized organotin cluster photoresists in organic solvents, including but not limit to, pentane, hexane, cyclohexane, dichlomethane, chloroform, tetrahydrofuran, dimethoxyethane, dimethylformamide, dimethyl sulfoxide, alcohols (e.g., 4-methyl-2-pentenol, methanol, ethanol, propanol, isopropanol, butanol), benzene, toluene, xylene, carboxylic acid, ethers (e.g., tetrahydrofuran, anisole), esters (e.g., ethyl acetate, ethyl lactate, butyl acetate), ketone (e.g., 2-heptanone, methyl ethyl ketone), or two or more mixtures thereof or the like. A person of ordinary skills in the art will recognize that the choice of solvents and solution composition components within the explicit ranges of above are contemplated and are within the present disclosure.

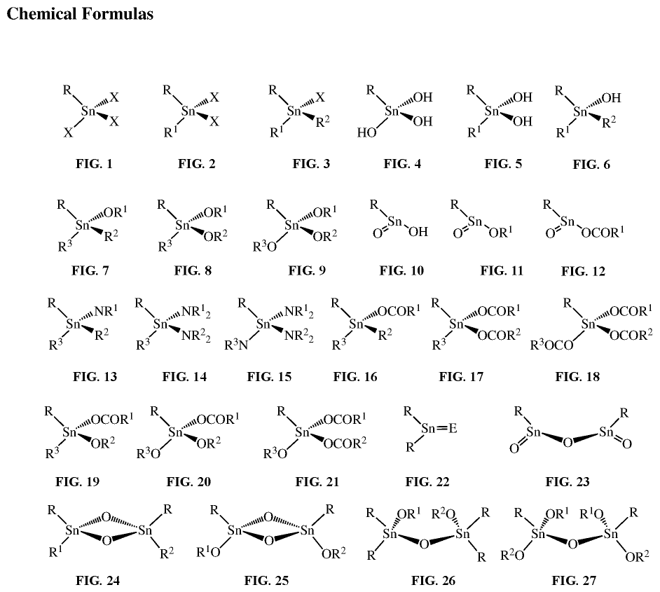

In an embodiment, organometallic tin compound precursors for preparation of organotin cluster photoresists, according to embodiments of the present disclosure, may be represented by at least one of examples. Examples of specific organometallic tin precursor materials that may be used in implementations of the invention are represented by FIGS. 1-27, including but not limited to, oxide hydroxide, alkoxide, amide, anhydride, halide, ester, or oxo, which contain hydrolysable functional groups, such as —NR′₂, —OR′, —X, —OCOR′.

In Chemical Formulas FIGS. 1-27, R is a substituted or unsubstituted cycloalkenyl group with 3 to 20 carbon atoms. R¹, R², R³ are independently H, a substituted or unsubstituted linear or branched alkyl, alkenyl, alkynyl, or cycloalkyl group with 1 to 20 carbon atoms, or a substituted or unsubstituted aryl groups with 6 to 20 carbon atoms. In some embodiments, cycloalkenyl group comprises a substituted and unsubstituted C4 to C8 cyclic aliphatic unsaturated organic groups including at least one double bond, for example, cyclopentadienyl C₅H₅(Cp), or substituted cyclopentadienyl C₅H₄R′, C₅H₃R′₂, C₅H₂R′₃, C₅HR′₄, or C₅R′₅ group with hapticity of η¹, η², η³, η⁴, or η⁵ of isomers.

In some embodiments, the invention pertains to organometallic tin compounds for preparation of organotin cluster compounds as photoresists, including organotin oxide hydroxide represented by chemical formula RSnO(OH), anhydride represented by chemical formula [(RSnO]₂O, halides represented by chemical formula RSnX₃, hydroxide represented by chemical formula RSn(OH)₃, alkoxides represented by chemical formula RSn(OR¹)(OR²)(OR³), amides represented by chemical formula RSn(NR¹₂)(NR²₂)(NR³₂), oxo represented by chemical formula [RSn(OR¹)(OR²)]₂(O), esters represented by chemical formula RSn(OCOR¹)(OCOR²)(OCOR³), or a combination thereof, wherein R is a substituted or unsubstituted cycloalkenyl group with 3 to 20 carbon atoms; R¹, R², R³ are independently H, a substituted or unsubstituted linear or branched alkyl, alkenyl, alkynyl, cycloalkyl, or cycloalkenyl group with 1 to 20 carbon atoms, or a substituted or unsubstituted aryl group with 6-20 carbon atoms, or other functional groups including amino, cyano, ether, ester, halide, nitro, silyl, thiol, or carbonyl group.

In some embodiments, the present invention pertains to organotin cluster photoresists bearing cycloalkenyl groups, for example (cyclopentadienyl)tin, (cycloheptatrienyl)tin. Organometallic (cyclopentadienyl)tin compounds comprise cyclopentadienyl C₅H₅, or substituted cyclopentadienyl C₅H₄R′, C₅H₃R′₂, C₅H₂R′₃, C₅HR′₄, or C₅R'₅ with hapticity of η¹, η², η³, η⁴, or η⁵ of isomers. Organometallic (cycloheptatrienyl)tin compounds comprise cycloheptatrienyl C₇H₇, or substituted cycloheptatrienyl C₇H₆R′, C₇H₅R′₂, C₇H₄R′₃, C₇H₃R′₄, C₇H₂R'₅, C₇HR′₆, or C₇R′₇ with the hapticity of η¹, η², η³, η⁴, η⁵, η⁶, or η⁷ of isomers. Wherein R′ is H, a substituted or unsubstituted alkyl, alkenyl, alkynyl, cycloalkyl group with 1 to 20 carbon atoms, a substituted or unsubstituted aryl group with 6-20 carbon atoms, or other functional groups including amino, cyano, ether, ester, halide, nitro, silyl, thiol, or carbonyl group, for example, but not limited to, methyl, ethyl, isopropyl, tert-butyl, tert-amyl, sec-butyl, pentyl, hexyl, neopentyl, cyclohexyl, cyclopentyl, cyclobutyl, cyclopropyl, or phenyl group.

Cyclopentadienyl group (C₅R'₅, or Cp) may impart photosensitivity to the compounds, and the Cₚ—Sn bond formed may promote suitable solubility in an organic solvent to the organometallic sandwich and half-sandwich tin compounds. Accordingly, these Cₚ—Sn bond-containing organometallic tin compounds according to an embodiment may have improved sensitivity, resolution and stability, and may suitable for EUV photoresists, and/or precursors for EUV lithography to form tin oxide or tin oxide hydroxide film.

The organometallic (cyclopentadienyl)tin clusters contain cyclopentadienyl-Sn bond (Cₚ—Sn bond). Cₚ—Sn bond is sensitive to UV light and occurs the radiation disruption to generate free radical when exposures to UV light, which has been demonstrated, for example, P. J. Baker, A. G. Davies, M.-W. Tse, “The Photolysis of cyclopentadienyl compounds of tin and mercury. Electron spin resonance spectra and electronic configuration of the cyclopentadienyl, deuteriocyclopentadienyl, and alkylcyclopentadienyl radicals”, Journal of Chemical Society, Perkin II, 1980, 941-948; S. G. Baxter, A. H. Cowley, J. G. Lasch, M. Lattman, W. P. Sharum, C. A. Stewart, “Electronic structures of bent-sandwich compounds of the main-group elements: A molecular orbital and UV photoelectron spectroscopic study of bis(cyclopentadienyl)tin and related compounds”, Journal of the American Chemical Society, 1982, 104, 4064-4069, all of which are incorporated herein by references. Baker, et. al. reported that the UV photolysis of unsubstituted sandwich and half-sandwich cyclopentadienyl-tin (IV) (C₅H₅—Sn) compounds, i.e., C₅H₅SnMe₃, C₅H₅SnBu₃, (C₅H₅)₂SnBu₂, C₅H₅SnCl₃, (C₅H₅)₂SnCl₂, (C₅H₅)₃SnCl, and (C₅H₅)₄Sn in toluene showed strong EPR spectra of the C₅H₅· radical. This study demonstrated cyclopentadienyl (C₅H₅) group or substituted cyclopentadienyl (C₅R₅) group has higher UV light sensitive compared with alkyl (e.g., methyl, butyl) groups under identical conditions. This property is beneficial to decrease EUV light dose and increase resolution.

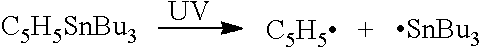

In some embodiments, organometallic (cyclopentadienyl)tin cluster photoresists may have excellent sensitivity to EUV radiation light due to the tin adsorption high energy EUV ray at 13.5 nm (low expose dose photoresist, e.g., <20 mJ/cm²), and the disruption of Cₚ—Sn bond to form free radical, tin oxide and relative products, and toughness; low or free pattern defectivity at nanoscale. Accordingly, the solution composition of organometallic (cyclopentadienyl)tin cluster photoresists may have tight pitch (e.g., <10 nm), and may sustain the yield and deliver high resolution.

The solution composition of organic molecules-stabilized organotin cluster photoresists bearing cycloalkenyl group and C_{cycloalkenyl}-Sn bond, such as cyclopentadienyl or substituted-cyclopentadienyl group, according to embodiments of the present disclosure, may have improved etch resistance, sensitivity, and resolution, compared with C_{alkyl}-Sn containing organotin photoresist.

The organotin cluster photoresists bearing cyclopentadienyl or substituted-cyclopentadienyl group, contain π bond, Cₚ—Sn bond, and/or relevant interaction, and may have excellent (e.g., suitable) sensitivity to high energy light (e.g., EUV, e-beam, X-ray, laser) due to tin adsorption high energy EUV ray at 13.5 nm. Accordingly, the related solution compositions may have improved sensitivity and stability compared with organic polymer or inorganic photoresists.

The solution composition of organotin cluster photoresists can be utilized for photolithography including deep ultraviolet radiation (DUV), extreme ultraviolet radiation (EUV), e-beam radiation, X-ray radiation, or ion-beam radiation for further processing and patterning.

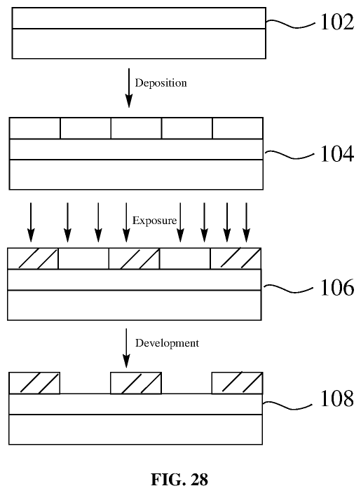

The general photolithography process described by FIG. 28, is to deposit photoresist over a substrate 102 to form a thin photoresist layer 104; after pre-exposure baking, the formed layer is exposed to actinic radiation to form a latent image 106; after post-exposure baking, the latent is developed by the appropriate developer, such as aqueous basic/acid solutions or organic solvents, to produce the developed resist photolithography pattern 108.

In some embodiments, after exposure, the exposed and unexposed portion of organotin cluster photoresists possess different chemical and physical properties. Organic ligands of organotin cluster photoresists can be cleaved from organotin cluster photoresists to form metal oxide or polynuclear oxo/hydroxo network patterns. The unexposed portion of photoresists can be removed by the developer due to different features, solubility, and properties.

The invention pertains to the methods for preparation and purification of organotin compounds represented by FIGS. 1-27, and organotin cluster compounds represented by chemical formulas [RR¹Sn]₃E₃, [RSn]₄E₆. All chemical manipulations, including preparation and purification, are performed under an inert atmosphere of purified nitrogen or argon in dry and degassed solvents by employing standard Schlenk techniques. The methods for purification of organotin compounds comprise distillation, extraction, filtration, recrystallization, column chromatography, coordination, sublimation, or combinations thereof.

In some embodiments, the solubility of organic molecules-stabilized organotin cluster photoresists in organic solvents may be improved, and dissolution during a photolithography such as EUV. Accordingly, a nanoscale pattern having improved stability, solubility, sensitivity and limited resolution may be afforded by using of organic molecules-stabilized organotin clusters photoresists. Additionally, the as-formed pattern by using of organic molecules-stabilized organotin cluster photoresists may not form scums and defects.

In addition, organotin cluster photoresists patterning according to an embodiment is not necessarily limited to the negative tone image but may be formed to have a positive tone image.

Hereinafter, the present invention is described in more details through Examples regarding the preparation of organotin cluster photoresists and stabilization methods of the present embodiments. However, the present invention is not limited by the Examples. A person of ordinary skills in the art will recognize that the samples and solution composition components within the explicit ranges of above are contemplated and are within the present disclosure.

### EXAMPLES

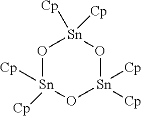

Synthesis of [Cp₂Sn]₃O₃. Cp₂SnCl₂ (Cₚ=cyclopentadienyl, C₅H₅) was prepared by the reaction of two equivalent cyclopentadienyl sodium (C₅H₅Na) or C₅H₅Li with one equivalent SnCl₄ (Caution: SnCl₄ is extremely hydrolytic when exposure to air or water and releasing HCl gaseous !!!) at low temperature, which was according to the reference: P. Jutzi, F. Kohl, Journal of Organometallic Chemistry 164 (1979) 141-152. To a refluxing solution of Cp₂SnCl₂ (1.16 g, 3.63 mmol) in toluene (50 mL), NaOH (290 mg, 7.26 mmol) in deoxygenized water (10 mL) was added dropwise with vigorously stirring. After addition, the mixture were refluxing for hours, then the organic phase was isolated and dried over MgSO₄. After filtered, the filtrate was evaporated in vacuo to give the product. Yield: 0.56 g, 60%. ¹H NMR (400.13 MHz, [D₈]THF) δ=5.93 (bs, 30H). MS (EI): m/z 794 (M⁺).

It is understood that the above-described examples and embodiments are intend to be illustrative purpose only. It should be apparent that the present invention has described with references to particular embodiments, and is not limited to the example embodiment as described, and may be variously modified and transformed. A person with ordinary skill in the art will recognize that changes can be made in form and detail without departing from the sprit and scope of this invention. Accordingly, the modified or transformed example embodiments as such may be understood from the technical ideas and aspects of the present invention, and the modified example embodiments are thus within the scope of the appended claims of the present invention and equivalents thereof.

What is claimed is:

1. An organotin cluster photoresist composition, comprising an organotin cluster compound, a solvent, and/or an additive,
wherein the organotin cluster compound is one or more selected from the following: 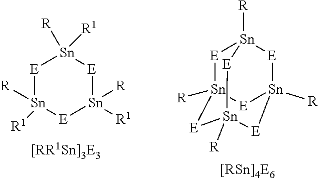
wherein R is a substituted or unsubstituted cycloalkenyl group with 3 to 20 carbon atoms; R¹ is a substituted or unsubstituted alkyl, alkenyl, alkynyl, cycloalkyl, or cycloalkenyl group with 1 to 20 carbon atoms, or a substituted or unsubstituted aryl group with 6-20 carbon atoms; E=O, S, Se, or Te.

2. The organotin cluster photoresist composition of claim 1, wherein cycloalkenyl group comprises a substituted and unsubstituted C4 to C8 cyclic aliphatic unsaturated organic groups including at least one double bond.

3. The organotin cluster photoresist composition of claim 2, wherein cycloalkenyl group comprises cyclopentadienyl C₅H₅ group, or substituted cyclopentadienyl C₅H₄R′, C₅H₃R′₂, C₅H₂R′₃, C₅HR′₄, or C₅R'₅ group with hapticity η¹, η², η³, η⁴, or η⁵ of isomers, wherein R′ is a substituted or unsubstituted alkyl, alkenyl, alkynyl, or cycloalkyl group with 1 to 20 carbon atoms, or a substituted or unsubstituted aryl group with 6-20 carbon atoms.

4. The organotin cluster photoresist composition of claim 1, wherein R is a cyclopentadienyl group; R¹ is an alkyl, an aryl, or a cyclopentadienyl group; wherein cyclopentadienyl comprises cyclopentadienyl C₅H₅ group, or substituted cyclopentadienyl C₅H₄R′, C₅H₃R′₂, C₅H₂R′₃, C₅HR′₄, or C₅R'₅ group.

5. The organotin cluster photoresist composition of claim 4, wherein R, R¹ are independently cyclopentadienyl group; R′ is methyl, ethyl, propyl, n-butyl, t-butyl, phenyl, benzyl, or cyclohexyl.

6. The organotin cluster photoresist composition of claim 1, wherein E=O.

7. The organotin cluster photoresist composition of claim 1, wherein the solvent comprises benzene, toluene, xylene, tetrahydrofuran, dimethoxyethane, methanol, 4-methyl-2-pentano, ethanol, propanol, butanol, or combinations thereof.

8. The organotin cluster photoresist composition of claim 1, wherein the additive comprises organic thiol, organic alcohol, organic amine, organic amide, organic carboxylic acid, organic phosphine, organic phosphine oxide, organic phosphonic acid, or combinations thereof.

9. A method of stabilizing organotin cluster photoresist for lithography patterning, comprising:
forming organic molecules stabilized organotin cluster photoresist composition;
depositing organotin cluster photoresist composition over a substrate to form a photoresist layer;
exposing the organotin cluster photoresist layer to actinic radiation; and
developing selectively portion of photoresists to form a pattern.

10. The method of claim 9, wherein the organotin cluster photoresist is one or more selected from the following: 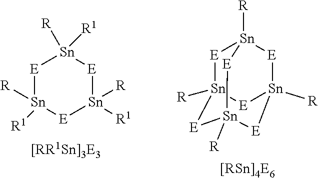
wherein R is a substituted or unsubstituted cycloalkenyl group with 3 to 20 carbon atoms; R¹ is a substituted or unsubstituted alkyl, alkenyl, alkynyl, cycloalkyl, or cycloalkenyl group with 1 to 20 carbon atoms, or a substituted or unsubstituted aryl group with 6-20 carbon atoms; E=O, S, Se, or Te.

11. The method of claim 10, wherein cycloalkenyl group comprises a substituted and unsubstituted C4 to C8 cyclic aliphatic unsaturated organic groups including at least one double bond.

12. The method of claim 11, wherein cycloalkenyl group comprises cyclopentadienyl C₅H₅ group, or substituted cyclopentadienyl C₅H₄R′, C₅H₃R′₂, C₅H₂R′₃, C₅HR′₄, or C₅R'₅ group with hapticity of η¹, η², η³, η⁴, or η⁵ of isomers, wherein R′ is a substituted or unsubstituted alkyl, alkenyl, alkynyl, or cycloalkyl group with 1 to 20 carbon atoms, or a substituted or unsubstituted aryl group with 6-20 carbon atoms.

13. The method of claim 10, wherein R is cyclopentadienyl; R¹ is an alkyl, aryl, or cyclopentadienyl; wherein cyclopentadienyl comprises cyclopentadienyl C₅H₅, or substituted cyclopentadienyl C₅H₄R′, C₅H₃R′₂, C₅H₂R′₃, C₅HR′₄, or C₅R'₅ group, wherein R′ is methyl, ethyl, propyl, n-butyl, t-butyl, phenyl, benzyl, or cyclohexyl.

14. The method of claim 9, wherein organic molecules comprise organic thiol, organic alcohol, organic amine, organic amide, organic carboxylic acid, organic phosphine, organic phosphine oxide, organic phosphonic acid, or combinations thereof.

15. The method of claim 14, wherein the organic molecules comprise 1-dodecanethiol, 2-dodecanethiol, 1,12-dodecanedithiol, 1-dodecanol, 1-octanol, 1-hexadecanol, 1-heptadecyloctadecylamine, decylamine, dodecylamine, decanamide, docosanamide, dodecanamide, oleic acid, citric acid, decanoic acid, hexadecanedioic acid, trioctylphosphine, tributylphosphine, trioctylphospine oxide, hexylphosphonic acid, octadecylphosphonic acid, 11-undecenyl phosphonic acid, or combinations thereof.

16. The method of claim 9, wherein the actinic radiation is extreme ultraviolet radiation, or deep ultraviolet radiation.

17. An organotin cluster photoresist, having a chemical structure selected from the following: 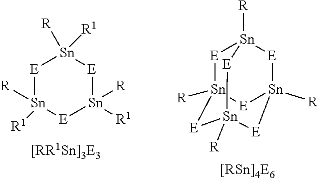
wherein R, R¹ are each independently cyclopentadienyl group, E=O, S, Se, or Te.

18. The organotin cluster photoresist of claim 17, wherein cyclopentadienyl comprises cyclopentadienyl C₅H₅, or substituted cyclopentadienyl C₅H₄R′, C₅H₃R′₂, C₅H₂R′₃, C₅HR′₄, or C₅R'₅ group with hapticity of η¹, η², η³, η⁴, or η⁵ of isomers, wherein R′ is a substituted or unsubstituted alkyl, alkenyl, alkynyl, or cycloalkyl group with 1 to 20 carbon atoms, or a substituted or unsubstituted aryl group with 6-20 carbon atoms.

19. The organotin cluster photoresist of claim 18, wherein R′ is methyl, ethyl, propyl, n-butyl, t-butyl, phenyl, benzyl, or cyclohexyl.

20. The organotin cluster photoresist of claim 17, wherein E=O.
